(19) United States
(12) Patent Application Publication
(10) Pub. No.: US 2012/0206146 A1
(43) Pub. Date: Aug. 16, 2012

(54) TECHNIQUE FOR IDENTIFYING AT LEAST ONE FAULTY LIGHT EMITTING DIODE IN A STRING OF LIGHT EMITTING DIODES

(75) Inventor: Jean-Jacques M. Avenel, Servon (FR)

(73) Assignee: Texas Instruments Incorporated, Dallas, TX (US)

(21) Appl. No.: 13/369,949

(22) Filed: Feb. 9, 2012

(30) Foreign Application Priority Data
Feb. 9, 2011 (EP) EP 11305129.6

(51) Int. Cl. G01R 31/00

(52) U.S. Cl. 324/414

(57) ABSTRACT

A method includes receiving a first voltage from an intermediate node in a string of multiple light emitting diodes (LEDs). The method also includes receiving at least one second voltage based on a string voltage (V_{LED}) across the string of LEDs. The method further includes identifying whether at least one of the LEDs has a fault using the first voltage and the at least one second voltage. The second voltage could be a single reference voltage, and a difference between the first voltage and the reference voltage could be compared to a threshold. Multiple second voltages could define a voltage range that includes a reference voltage, and a determination could be made whether the first voltage falls within the voltage range.

### CROSS-REFERENCE TO RELATED APPLICATIONS

This application claims priority under 35 U.S.C. §119 to European Patent Application No. EP 11305129 filed on Feb. 9, 2011, which is hereby incorporated by reference.

### TECHNICAL FIELD

This disclosure is generally directed to light emitting diodes (LEDs). More specifically, this disclosure is directed to a technique for identifying at least one faulty LED in a string of LEDs.

### BACKGROUND

Many systems use light emitting diodes (LEDs) to generate illumination. For example, vehicles often use headlamps containing strings of LEDs. A string of LEDs typically includes multiple LEDs coupled in series, where a current through the string causes the LEDs to illuminate.

It is often difficult to determine whether a single LED or a small subset of LEDs in a string has shorted out or otherwise suffered a fault. As a particular example, assume that a string includes ten LEDs coupled in series. The voltage across each LED could normally vary between 2.6V and 4.0V, so the voltage across the entire string could vary between 26V and 40V. In this case, it would be difficult to detect an approximate 3V variation caused by a short circuit of one LED in the string.

### BRIEF DESCRIPTION OF DRAWINGS

For a more complete understanding of this disclosure and its features, reference is now made to the following description, taken in conjunction with the accompanying drawings, in which:

FIG. 1 illustrates a first example system for identifying at least one faulty light emitting diode (LED) in a string of LEDs according to this disclosure;

FIG. 2 illustrates a second example system for identifying at least one faulty LED in a string of LEDs according to this disclosure; and

FIG. 3 illustrates an example method for identifying at least one faulty LED in a string of LEDs according to this disclosure.

### DETAILED DESCRIPTION

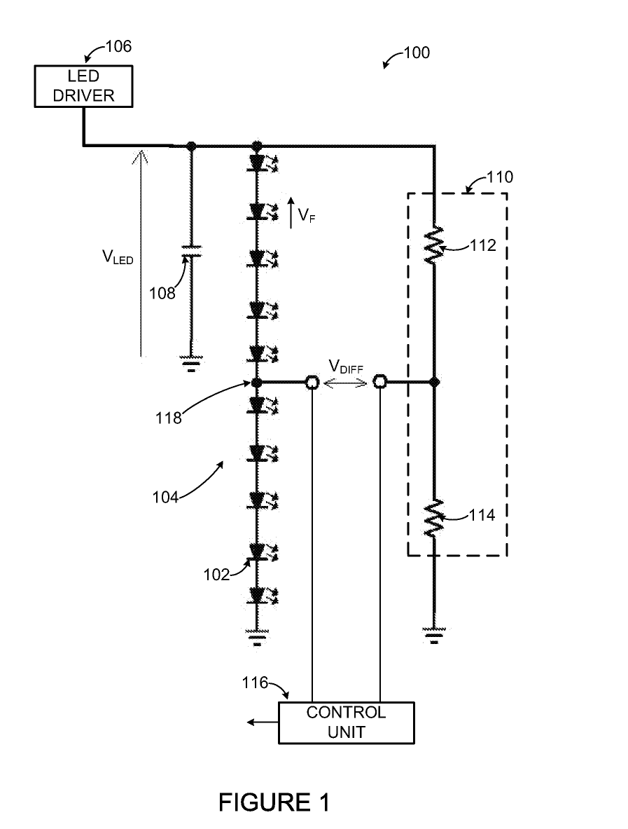

FIGS. 1 through 3, discussed below, and the various embodiments used to describe the principles of the present invention in this patent document are by way of illustration only and should not be construed in any way to limit the scope of the invention. Those skilled in the art will understand that the principles of the invention may be implemented in any type of suitably arranged device or system.

FIG. 1 illustrates a first example system 100 for identifying at least one faulty light emitting diode (LED) in a string of LEDs according to this disclosure. As shown in FIG. 1, the system 100 includes or is coupled to multiple LEDs 102. Each LED 102 represents any suitable semiconductor structure for generating visible light or other illumination. The LEDs 102 are coupled in series to form a string 104. In this example, there are ten LEDs 102 in the string 104, although any number of LEDs 102 could be used in the string 104. Also, while only one string 104 is shown here, any number of strings 104 could be used, such as multiple strings 104 coupled in parallel.

An LED driver 106 drives the LEDs 102 and causes the LEDs 102 to generate illumination. For example, the LED driver 106 could repeatedly turn the LEDs 102 on and off at a specified duty cycle to generate a specified amount of illumination. The LED driver 106 could also control the peak current through the LEDs 102, the average current through the LEDs 102, or some other aspect of the LEDs 102. The LED driver 106 includes any suitable structure for driving at least one string of LEDs.

An output capacitor 108 is coupled in parallel with the string 104 of LEDs 102. The output capacitor 108 represents any suitable capacitive structure having any suitable capacitance. In this example, a voltage across the output capacitor 108 (which is also the voltage across the LED string 104) is denoted V_{LED} and represents the string voltage of the LEDs 102.

A forward voltage V_{F} across each LED 102 in the string 104 could vary widely during normal operation, such as between 2.6V and 4.0V. This variation could be caused by any number of factors, such as temperature variations, driving current changes, or design differences. Because the voltage V_{LED} across the LED string 104 varies naturally, it is often difficult to detect variations caused by a short circuit or other fault in one or several of the LEDs 102.

In accordance with this disclosure, the system 100 implements a technique for detecting when one or more LEDs 102 in a string 104 experience a short circuit condition or other fault. A reference voltage is generated based on the LED voltage V_{LED}. In this embodiment, the reference voltage is generated by providing the LED voltage V_{LED} to a voltage divider 110 formed by resistors 112-114. The voltage divider 110 generates a scaled version of the LED voltage V_{LED}, which represents the reference voltage and is provided to a control unit 116.

The control unit 116 also receives a voltage associated with an intermediate node 118 within the LED string 104. An “intermediate node” denotes a node in an LED string that follows a first LED's output in the string and that precedes a last LED's input in the string. In this example, the intermediate node 118 represents the mid-point of the LED string 104, meaning half of the LEDs 102 are on each side of the intermediate node 118.

The control unit 116 uses the voltages associated with the voltage divider 110 and the intermediate node 118 to determine if a fault has occurred with one or more of the LEDs 102 in the string 104. For example, the control unit 116 could determine whether a voltage difference V_{DIFF} between the voltage from the voltage divider 110 and the voltage from the intermediate node 118 exceeds a threshold. The voltage difference V_{DIFF} may be relatively small (even approaching zero) when all LEDs 102 in the string 104 are operating properly. However, the voltage difference V_{DIFF} can increase dramatically if at least one LED 102 in the string 104 short circuits.

As a particular example, the voltage difference V_{DIFF} might not exceed several hundred millivolts (such as about 200 mV) when all LEDs 102 are operating properly, even over a wide range of temperatures (such as about 0° C. to about 90° C.) and driving currents (such as about 50 mA to about 350 mA). However, if one of the LEDs 102 in the string 104 shorts, the voltage difference V_{DIFF} could increase substantially, such as up to about V_{F}/2 (which could be around 1.6V in specific cases).

By comparing the voltage difference V_{DIFF} to a threshold, the control unit 116 can detect if and when one or more of the LEDs 102 in the string 104 shorts. The control unit 116 could then take any suitable corrective action. For example, the control unit 116 could output a signal indicating that a fault has been detected. The signal could be provided to any suitable destination, such as the LED driver 106 or an external controller or other device or system. In this way, the voltage difference V_{DIFF} can be used to identify a fault in one or more LEDs 102 over a wide range of temperatures, driving currents, or other variations.

The voltage divider 110 includes any suitable structure for scaling or otherwise dividing an input voltage. Each resistor 112-114 includes any suitable resistive structure having any suitable resistance, such as a 10 Ω±1% resistor. The control unit 116 includes any suitable structure for identifying a fault in one or more LEDs. For instance, the control unit 116 could include at least one comparator for comparing the voltage difference to a threshold value.

In this example, the intermediate node 118 is located directly in the middle of the LED string 104. As a result, the voltage normally expected at the intermediate node 118 would be about one-half of the string voltage V_{LED}. In this case, the resistors 112-114 could have substantially equal resistances in order to divide the string voltage V_{LED} substantially in half. However, the intermediate node 118 could be located in other positions within the LED string 104, and it might not be possible for the intermediate node 118 to be located in the middle of the string 104. For example, if the string 104 includes nine LEDs 102, the intermediate node 118 could be located between the fourth and fifth LEDs 102. In this case, the resistors 112-114 could have different resistances, such as 4/9R and 5/9R, respectively. This allows the voltage divider 110 to output the approximate voltage that would be expected at the intermediate node 118 during normal operation.

The system 100 shown in FIG. 1 could form part of any larger device or system. For example, the LEDs 102 could form part or all of a vehicle headlamp. The LEDs 102 could also form part or all of a display in a mobile telephone, a laptop computer, a desktop computer monitor, or other display device.

Although FIG. 1 illustrates a first example of a system 100 for identifying at least one faulty LED 102 in a string 104 of LEDs, various changes may be made to FIG. 1. For example, the system 100 could include any number of LEDs 102, LED strings 104, LED drivers 106, capacitors 108, voltage dividers 110, resistors 112-114, and control units 116. Also, various components in FIG. 1 could be combined, further subdivided, rearranged, or omitted and additional components could be added according to particular needs. For instance, the control unit 116 could be incorporated into the LED driver 106. Further, it is assumed here that the LEDs 102 have substantially common operating characteristics (such as common forward voltage variations over temperature and drive current). This could be done by using LEDs having a common brightness index number (BIN). Note, however, that the specific reference voltage from the voltage divider 110 could be adjusted to allow any combination of LEDs to be used in the system 100. In addition, while shown as being used with a single intermediate node 118, voltages at multiple intermediate nodes 118 could be monitored and analyzed, such as by duplicating various components in FIG. 1 (like the voltage divider 110 and possibly the control unit 116) and/or by using one or more multiplexers.

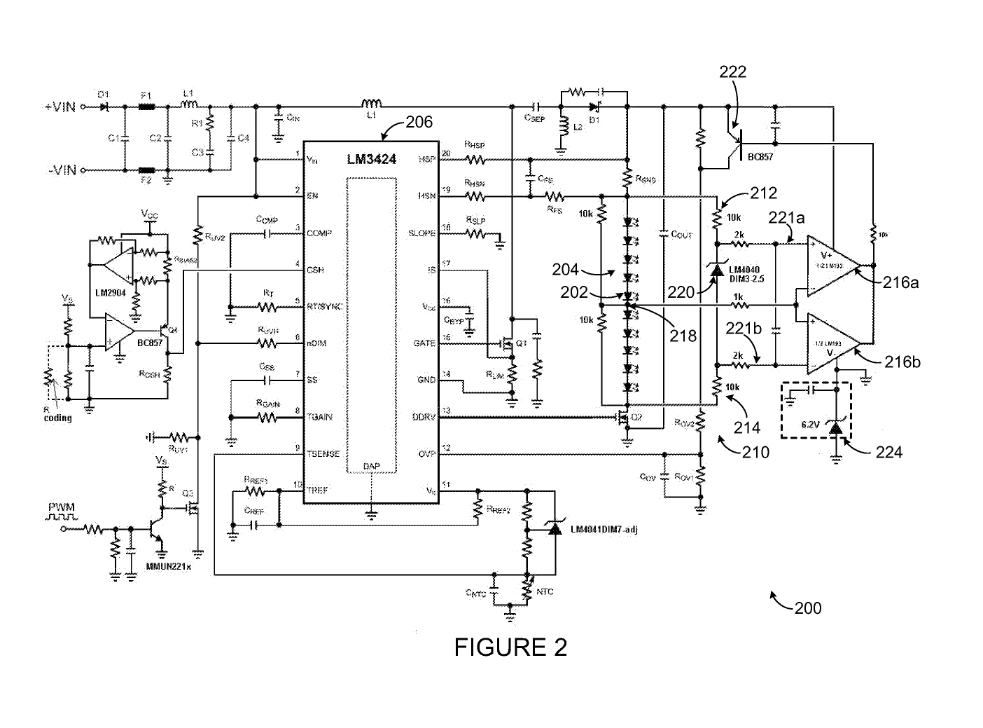

FIG. 2 illustrates a second example system 200 for identifying at least one faulty LED in a string of LEDs according to this disclosure. In particular, FIG. 2 illustrates a more specific implementation of the LED fault detection mechanism described above with respect to FIG. 1.

As shown in FIG. 2, the system 200 includes multiple LEDs 202 coupled in series to form a string 204. An LED driver 206 is used to drive the LEDs 202 in order to generate illumination. In this example, the LED driver 206 represents an LM3424 LED controller from NATIONAL SEMICONDUCTOR CORPORATION. However, any other suitable LED driver 206 could be used in the system 200.

A voltage divider 210 is formed using two resistors 212-214, where a voltage source 220 is inserted between the resistors 212-214. Here, the voltage source 220 represents an LM4040 precision reference voltage source from NATIONAL SEMICONDUCTOR CORPORATION, although any other suitable voltage source 220 could be used. The presence of the voltage source 220 within the voltage divider 210 creates two output voltages 221a-221b on opposite sides of the voltage source 220. Effectively, the output voltages 221a-221b of the voltage divider 210 define a voltage range that is centered on a reference voltage, where the size of the range is defined by the voltage source 220.

The output voltages 221a-221b of the voltage divider 210 are provided to two comparators 216a-216b. In this example, the comparators 216a-216b are implemented using a single LM193 dual comparator from NATIONAL SEMICONDUCTOR CORPORATION, although any other suitable comparators could be used. The comparator 216a compares the higher output voltage 221a of the voltage divider 210 to a voltage associated with an intermediate node 218 in the LED string 204. The comparator 216b compares the lower output voltage 221b of the voltage divider 210 to the voltage associated with the intermediate node 218.

When the voltage associated with the intermediate node 218 is within the range defined by the higher and lower output voltages 221a-221b from the voltage divider 210, both comparators 216a-216b output low logic values. When the voltage associated with the intermediate node 218 is not within the range defined by the higher and lower output voltages 221a-221b, one of the comparators 216a-216b outputs a high logic value. The high logic value acts as an indication of whether the voltage associated with the intermediate node 218 is within a range of expected voltages.

In this example, the outputs of the comparators 216a-216b are coupled to a gate of a transistor 222. When the output of either comparator 216a-216b goes high, the transistor 222 turns on, which alters the voltage received at an over-voltage protection (OVP) circuit within the LED driver 206. This could trigger an over-voltage lock-out (OVLO) in the LED driver 206. In this example, the transistor 222 represents a BC857 PNP bipolar transistor from NXP B.V., although any other suitable transistor 222 could be used. Also, note that any other or additional corrective action could be taken in the system 200 when the output of either comparator 216a-216b goes high.

In FIG. 2, the components within the dashed box 224 may be optional. In some embodiments, the V-input of the comparator 216b could be coupled directly to ground. However, if the voltage across the LED string 204 exceeds a specified voltage level (such as 36V), the components within the dashed box 224 could be coupled to the V-input of the comparator 216b.

The remaining components in FIG. 2 are used in conjunction with the LED driver 206 to achieve desired functionality. The remaining components include diodes, fuses, resistors, capacitors, inductors, bipolar and MOSFET transistors, and voltage comparators. These components are related to setting up and operating the specific LED driver 206 shown here and are not discussed further since a person skilled in the art would understand the use of these components with the specified LED driver 206.

In this way, the system 200 once again is able to detect when a voltage associated with the intermediate node 218 deviates from an expected voltage. This deviation can be indicative of a shorted LED 202 or other problem, and the system 200 can take suitable corrective action.

As with FIG. 1, the system 200 of FIG. 2 has the intermediate node 218 in the middle of the LED string 204. However, the intermediate node 218 could be placed at any other suitable intermediate position within the LED string 204. In that case, the design of the voltage divider 210 can be modified based on the position of the intermediate node 218 in order to provide appropriate higher and lower output voltages 221a-221b to the comparators 216a-216b. Also, multiple intermediate nodes 218 could be monitored, which could involve the use of multiple voltage dividers and multiplexers.

Although FIG. 2 illustrates a second example of a system 200 for identifying at least one faulty LED 202 in a string 204 of LEDs, various changes may be made to FIG. 2. For example, the system 200 could include any number of each component. Also, various components in FIG. 2 could be combined, further subdivided, rearranged, or omitted and additional components could be added according to particular needs. Moreover, it is assumed that the LEDs 202 have substantially common operating characteristics, although the voltage divider 210 could be adjusted to provide any suitable reference voltage range. Further, while specific components and component values (such as specific parts, resistances, voltages, and logic levels) are shown in FIG. 2 or described above, these components and component values are for illustration only. Any other or additional circuit components could be used to provide the desired functionality in the system 200. In addition, features shown in FIG. 1 could be used in FIG. 2 or vice versa. For instance, the voltage divider 110 in FIG. 1 could output multiple voltages 221a-221b defining a range of acceptable values, and the control unit 116 could use multiple comparators 216a-216b to detect LED faults using this range.

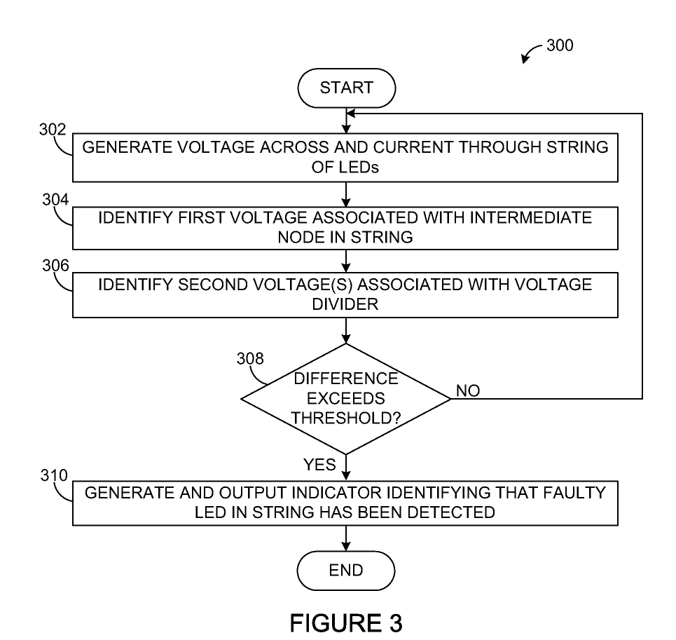

FIG. 3 illustrates an example method 300 for identifying at least one faulty LED in a string of LEDs according to this disclosure. The method 300 could be used with any suitable system, including the system 100 of FIG. 1, the system 200 of FIG. 2, or other system.

As shown in FIG. 3, a voltage is generated across and a current is generated through a string of LEDs at step 302. This could include, for example, the LED driver 106 or 206 generating a string voltage V_{LED} and a current through the LEDs 102 or 202. The string voltage V_{LED} and the current could be generated in order to provide a desired level of illumination from the string 104 or 204 of LEDs 102 or 102.

A first voltage associated with an intermediate node in the string is identified at step 304, and at least one second voltage associated with a voltage divider is identified at step 306. This could include, for example, receiving a first voltage associated with the intermediate node 118 or 218 in the string 104 or 204. The second voltage could be a single voltage representing a reference voltage (from the voltage divider 110) or multiple voltages centered around a reference voltage (from the voltage divider 210).

A determination is made whether a difference between the first and second voltages exceeds a threshold at step 308. This could include, for example, the control unit 116 determining a difference between the first and second voltages and comparing the difference to a threshold. This could also include the voltage divider 210 outputting multiple second voltages 221a-221b defining a range around a reference voltage and the comparators 216a-216b determining whether the first voltage falls within the range. Any other suitable technique could be used to identify whether a difference between first and second voltages exceeds a threshold.

If no threshold violation occurs, the method 300 returns to step 302, and the system may continue to generate illumination using the LED string. If a threshold violation occurs, this is indicative of an LED short or other fault in the LED string. In that case, corrective action can be taken, such as generating and outputting an indicator identifying that one or more faulty LEDs have been detected in the string at step 310. Any other or additional corrective action could be taken, such as shutting off the LEDs 102 or 202 or adjusting the voltage across or current through the LEDs.

Although FIG. 3 illustrates one example of a method 300 for identifying at least one faulty LED in a string of LEDs, various changes may be made to FIG. 3. For example, while shown as a series of steps, various steps in FIG. 3 could overlap, occur in parallel, occur in a different order, or occur any number of times.

It may be advantageous to set forth definitions of certain words and phrases that have been used within this patent document. The term “couple” and its derivatives refer to any direct or indirect communication between two or more components, whether or not those components are in physical contact with one another. The terms “include” and “comprise,” as well as derivatives thereof, mean inclusion without limitation. The term “or” is inclusive, meaning and/or. The phrase “associated with”, as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like.

While this disclosure has described certain embodiments and generally associated methods, alterations and permutations of these embodiments and methods will be apparent to those skilled in the art. Accordingly, the above description of example embodiments does not define or constrain this invention. Other changes, substitutions, and alterations are also possible without departing from the spirit and scope of this invention as defined by the following claims.

What is claimed is:

1. An apparatus comprising:
a control unit configured to receive (i) a first voltage from an intermediate node in a string of multiple light emitting diodes (LEDs) and (ii) at least one second voltage based on a string voltage across the string of LEDs;
the control unit also configured to identify whether at least one of the LEDs has a fault using the first voltage and the at least one second voltage.

2. The apparatus of claim 1, wherein:
the control unit is configured to receive a single second voltage defining a reference voltage; and
the control unit is configured to compare a difference between the first voltage and the reference voltage to a threshold.

3. The apparatus of claim 1, wherein:
the control unit is configured to receive multiple second voltages defining a voltage range that includes a reference voltage; and
the control unit is configured to determine whether the first voltage falls within the voltage range.

4. The apparatus of claim 1, further comprising:
a voltage divider coupled in parallel with the string of LEDs and configured to generate the at least one second voltage.

5. The apparatus of claim 4, wherein the voltage divider comprises multiple resistors and a reference voltage source coupled in series between the resistors.

6. The apparatus of claim 5, wherein the control unit comprises:
multiple comparators configured to compare the first voltage to multiple second voltages from the voltage divider, the multiple second voltages provided on opposite sides of the reference voltage source.

7. The apparatus of claim 1, wherein the control unit is configured to be coupled to the string of LEDs in a vehicle headlamp.

8. The apparatus of claim 1, wherein the control unit is configured to be coupled to the string of LEDs in a display of an electronic device.

9. A system comprising:
a string of multiple light emitting diodes (LEDs);
a control unit configured to receive (i) a first voltage from an intermediate node in the string of LEDs and (ii) at least one second voltage based on a string voltage across the string of LEDs; and
a voltage divider coupled in parallel with the string of LEDS and configured to generate the at least one second voltage;
wherein the control unit is configured to identify whether at least one of the LEDs has a fault using the first voltage and the at least one second voltage.

10. The system of claim 9, wherein:
the intermediate node in the string of LEDs is located at a mid-point of the string; and
the voltage divider comprises multiple resistors having substantially equal resistances.

11. The system of claim 9, wherein the voltage divider is configured so that the at least one second voltage is within about 200 mV of the first voltage during normal operation of the LEDs.

12. The system of claim 9, wherein:
the control unit is configured to receive a single second voltage defining a reference voltage; and
the control unit is configured to compare a difference between the first voltage and the reference voltage to a threshold.

13. The system of claim 9, wherein:
the control unit is configured to receive multiple second voltages defining a voltage range that includes a reference voltage; and
the control unit is configured to determine whether the first voltage falls within the voltage range.

14. The system of claim 9, wherein:
the voltage divider comprises multiple resistors and a reference voltage source coupled in series between the resistors; and
the control unit comprises multiple comparators configured to compare the first voltage to multiple second voltages from the voltage divider, the multiple second voltages provided on opposite sides of the reference voltage source.

15. The system of claim 9, wherein the string of LEDs comprises a string of LEDs in a vehicle headlamp.

16. The system of claim 9, wherein the string of LEDs comprises a string of LEDs in a display of an electronic device.

17. A method comprising:
receiving a first voltage from an intermediate node in a string of multiple light emitting diodes (LEDs);
receiving at least one second voltage based on a string voltage across the string of LEDs; and
identifying whether at least one of the LEDs has a fault using the first voltage and the at least one second voltage.

18. The method of claim 17, wherein:
receiving the second voltage comprises receiving a single second voltage defining a reference voltage; and
identifying whether at least one of the LEDs has a fault comprises comparing a difference between the first voltage and the reference voltage to a threshold.

19. The method of claim 17, wherein:
receiving the second voltage comprises receiving multiple second voltages defining a voltage range that includes a reference voltage; and
identifying whether at least one of the LEDs has a fault comprises determining whether the first voltage falls within the voltage range.

20. The method of claim 17, wherein the string of LEDs comprises a string of LEDs in a vehicle headlamp.
